(19) United States
(12) Patent Application Publication
(10) Pub. No.: US 2024/0196555 A1
(43) Pub. Date: Jun. 13, 2024

(54) HOUSING INCLUDING INSULATION MEMBER, ELECTRONIC DEVICE INCLUDING THE SAME AND METHOD OF PROVIDING THE SAME

(71) Applicant: SAMSUNG ELECTRONICS CO., LTD., Suwon-si (KR)

(72) Inventors: Hangyu HWANG, Suwon-si (KR); Yoonhee LEE, Suwon-si (KR)

(21) Appl. No.: 18/442,621

(22) Filed: Feb. 15, 2024

Related U.S. Application Data
(63) Continuation of application No. PCT/KR2022/012606, filed on Aug. 23, 2022.

(30) Foreign Application Priority Data
Aug. 23, 2021 (KR) 10-2021-0110872

(51) Int. Cl. H05K 5/04; B29C 37/00; B29C 65/48; B29C 65/64; B29C 65/70; B29C 65/72; B29L 31/34; H04M 1/02; H05K 5/00

(52) U.S. Cl. CPC H05K 5/04; B29C 37/0025; B29C 65/48; B29C 65/64; B29C 65/70; B29C 65/72; H04M 1/0249; H05K 5/0086; B29K 2995/0093; B29L 2031/3481

(57) ABSTRACT

An electronic device including a housing defining an outer surface of the electronic device. The housing includes metal regions comprising a surface treatment layer defining the outer surface at the metal regions, and an insulation region which is between the metal regions and coupled to each of the metal regions. The insulation region includes a polymer material portion, and a coating layer which is on the polymer material portion and defines the outer surface at the insulation region. The coating layer comprising a polymer matrix and siloxane.

### CROSS-REFERENCE TO RELATED APPLICATIONS

This application is a continuation application of International Application No. PCT/KR2022/012606 designating the United States, filed on Aug. 23, 2022, in the Korean Intellectual Property Receiving Office and claiming priority to Korean Patent Application No. 10-2021-0110872, filed on Aug. 23, 2021, in the Korean Intellectual Property Office, the disclosures of which are incorporated by reference herein in their entireties.

### BACKGROUND

### (1) Field

Various embodiments disclosed herein relate to surface treatment of an electronic device. More particularly, one or more embodiment disclosed herein relates to an electronic device including a housing including an insulation member, and a method for manufacturing (or providing) the same.

### (2) Description of the Related Art

An electronic device may include an antenna for wireless communication. The antenna of the electronic device may protrude out of the electronic device, or may be positioned within the electronic device as a chip antenna. An electronic device may include multiple antennas in order to perform wireless communication according to multiple communication standards or by means of multiple frequency bands.

Metal materials have high levels of strength and impact toughness, and thus are widely used for housings of portable electronic devices. If a metal material constituting the housing of an electronic device is utilized as an antenna, an inner space may be secured by improving the appearance of the electronic device.

If a metal material included in the housing of an electronic device is used for multiple antennas, the housing may include multiple metal regions including the metal material and an insulation region electrically separating the multiple metal regions from each other. The insulation region may include a polymer material which is highly insulative.

### SUMMARY

In general, metal materials are susceptible to corrosion, and an oxide film may be formed on the metal surface to prevent corrosion and contamination. If the housing of an electronic device including a metal region and an insulation region is subjected to surface treatment, the insulation region including a polymer material may have an increased level of surface roughness and may undergo surface whitening because inorganic components included in the anodizing solution remain on the surface. Such whitening of the insulation zone may increase the degree of dissimilarity to the metal region in terms of color and illuminance.

Various embodiments disclosed herein may provide an electronic device including a housing including a coating layer configured to reduce the whitening of the insulation region surface and to reduce the degree of dissimilarity to the metal region.

In addition, various embodiments disclosed herein may provide a method for manufacturing (or providing) an electronic device including a housing having the above-mentioned characteristics.

An electronic device according to various embodiments of the disclosure may be an electronic device including a housing, where the housing includes multiple metal regions including a surface treatment layer formed (or provided) on a surface exposed to an outer surface of the electronic device (e.g., an outer surface), and an insulation region exposed to the outer surface of the electronic device, positioned between the metal regions, and coupled to the metal regions, the insulation region including a polymer material, and where the insulation region includes a coating layer including a polymer matrix and a siloxane-based material, the coating layer being formed on a surface of the insulation region, the surface being exposed to the outer surface of the electronic device. In embodiments, the level difference between the surface of the surface treatment layer and the surface of the coating layer may be about 1 micrometer or less. In embodiments, the coating layer may have a water-repellent surface.

In embodiments, the coating layer surface may have a lower degree of roughness than the surface of the insulation region. In embodiments, the metal region may include a surface roughened by at least one of a physical roughening method or a chemical roughening method.

In embodiments, the siloxane-based material may include dimethylsiloxane. In embodiments, the surface treatment layer may include an anodized layer.

In embodiments, the polymer matrix may include acrylate and/or epoxy polymer, and the coating layer may have transparency. In an embodiment, the surface of the insulation region may include multiple protrusions, and the coating layer may have a refractive index lower than the refractive index of the protrusions.

A method for manufacturing (or providing) an electronic device housing according to an embodiment of the disclosure may be a method for manufacturing an electronic device housing including a metal region and an insulation region. The method includes a material molding operation of coupling a metal material and a polymer material to each other and machining the coupled metal material and polymer material according to a contour of the electronic device housing, a surface treatment operation of treating the surface of the metal region subjected to the machining operation, and a coating operation of applying a coating solution to the surface of the polymer material exposed to the surface of the housing, the coating solution including a liquid resin-state polymer matrix and a siloxane-based material. In embodiments, the siloxane-based material may include dimethylsiloxane. In embodiments, the coating solution may include acrylate and/or epoxy paint. In embodiments, the coating solution may include an organic solvent for dissolving the polymer material.

In embodiments, the machining operation may include a first processing operation of roughing the metal material, a molding operation of molding the polymer material and coupling the molded polymer material and the metal material processed in the first processing operation, and a second processing operation of finishing the metal material and the polymer material into a final shape of the electronic device housing.

In embodiments, the surface treatment operation may include a roughening operation of increasing the surface roughness of the electronic device housing. In embodiments, the surface treatment operation may include an anodizing operation of immersing the electronic device housing in an anodizing solution and applying a current to the metal material such that an anodized layer is formed on the surface of the metal material. In embodiments, the roughening operation may include a blasting operation of spraying beads to the surface of the electronic device housing. In embodiments, the roughening operation may include an operation of immersing the electronic device housing in a corrosive solution so as to be etched.

In embodiments, the coating operation may include an operation of precisely printing the coating solution on the surface of the insulation region exposed to the outside of the electronic device. In embodiments, the precisely printing operation may include an operation of transferring the coating solution to the surface of the insulation region by digital direct printing (DDP).

Various embodiments disclosed herein may provide an electronic device including a housing including a coating layer which is formed on a surface of an insulation region and exposed to outside of the electronic device, and which includes a siloxane-based material such that, by reducing the whitening of the insulation region, the appearance has a low level of dissimilarity, a low level of gloss deviation, and a high level of flatness/smoothness.

In addition, a method for manufacturing an electronic device housing may be provided, the method including an operation of applying a coating solution including a siloxane-based material to the surface of an insulation region to provide the outer surface of the electronic device, after an operation of surface-treating the housing of the electronic device, thereby reducing whitening.

### BRIEF DESCRIPTION OF THE DRAWINGS

The above and other advantages and features of this disclosure will become more apparent by describing in further detail embodiments thereof with reference to the accompanying drawings, in which:

FIG. 1 is a block diagram illustrating the internal configuration of an electronic device according to an embodiment of the disclosure.

FIG. 2A is a front perspective view of an electronic device according to various embodiments of the disclosure.

FIG. 2B is a rear perspective view of an electronic device according to various embodiments of the disclosure.

FIG. 2C is an exploded perspective view of an electronic device according to various embodiments of the disclosure.

FIG. 3A is a lateral view of a housing of an electronic device according to various embodiments of the disclosure.

FIG. 3B is a cross-sectional view of the housing of the electronic device.

FIG. 3C is an enlarged cross-sectional view of the housing of the electronic device.

FIG. 4 is a flowchart illustrating a method of providing an electronic device housing according to various embodiments of the disclosure.

FIG. 5A, FIG. 5B, FIG. 5C, and FIG. 5D are cross-sectional views illustrating sections of an electronic device housing according to respective operations of a method for manufacturing (or providing) an electronic device housing according to various embodiments of the disclosure.

FIG. 6A illustrates the appearance of an electronic device housing according to a comparative example.

FIG. 6B illustrates the appearance of an electronic device housing according to an embodiment of the disclosure.

FIG. 6C illustrates water repellency of an electronic device housing according to a comparative example.

FIG. 6D illustrates water repellency of an electronic device housing according to an embodiment of the disclosure.

### DETAILED DESCRIPTION

Hereinafter, exemplary embodiments of the disclosure will be described in detail with reference to the accompanying drawings. In the drawings, for example, the sizes and shapes of elements may be exaggerated for the convenience of description, and it may be expected that the illustrated shaped are changed when the elements are actually implemented. Therefore, embodiments of the disclosure is not limited by the particular shapes of areas shown in the specification.

Throughout the specification, the same or like reference signs designate the same or like elements.

As used in the specification, the term “and/or” includes any one or all possible combinations of one or more items enumerated together.

The embodiments of the disclosure are provided to completely explain the disclosure to those skilled in the art, the following embodiments may be modified in various other forms, and the scope of the disclosure is not limited to the following embodiments. Instead, the embodiments are provided to make the disclosure more complete and completely transfer the idea of the disclosure to those skilled in the art.

The terms used in the specification are used to describe embodiments, and are not intended to limit the scope of the disclosure. Although expressed in a singular form, the singular form may include a plural form unless definitely indicated in the context.

As used herein, the term “comprise” or “comprising” is intended to specify the existence of mentioned shapes, numbers, steps, operations, elements, components, and/or groups thereof, and does not preclude the possible existence or addition of other shapes, numbers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

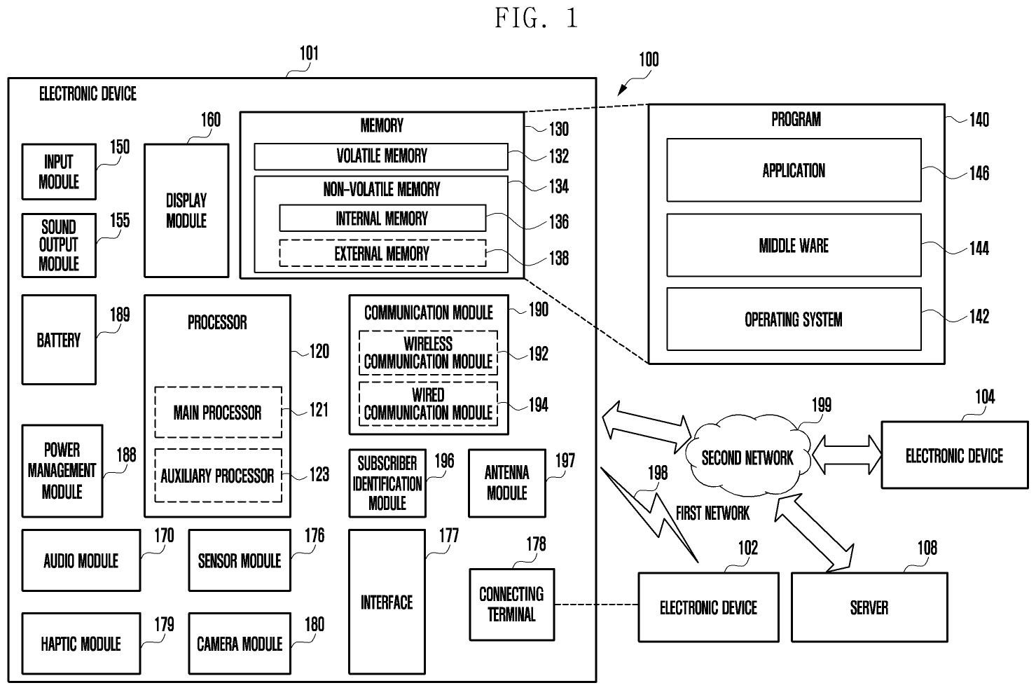

FIG. 1 is a block diagram illustrating an electronic device 101 in a network environment 100 according to various embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module(SIM) 196, or an antenna module 197. In embodiments, at least one of the components (e.g., the connecting terminal 178) may be omitted from the electronic device 101, or one or more other components may be added in the electronic device 101. In embodiments, components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. Within the Figures and the text of the disclosure, a reference number indicating a singular form of an element may also be used to reference a plurality of the singular element.

It is to be understood that a singular form of a noun corresponding to an item may include one or more of the things, unless the relevant context clearly indicates otherwise. . As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. “At least one” is not to be construed as limiting “a” or “an.” “Or” means “and/or.”

As used herein, such terms as “1^{st}” and “2^{nd},” or “first” and “second” may be used to simply distinguish a corresponding component from another, and does not limit the components in other aspect (e.g., importance or order).

It is to be understood that if an element (e.g., a first element) is referred to, with or without the term “operatively” or “communicatively”, as being related to another element such as being “coupled with,” “coupled to,” “connected with,” or “connected to” another element (e.g., a second element), it means that the element may be coupled with the other element directly (e.g., physically in contact, providing an interface therebetween, wiredly), wirelessly, or via a third element. In contrast, when a first element is referred to as being related to another element such as being “directly coupled with,” “directly coupled to,” “directly connected with,” or “directly connected to” a second element, it means that no third element is present therebetween.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Where, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

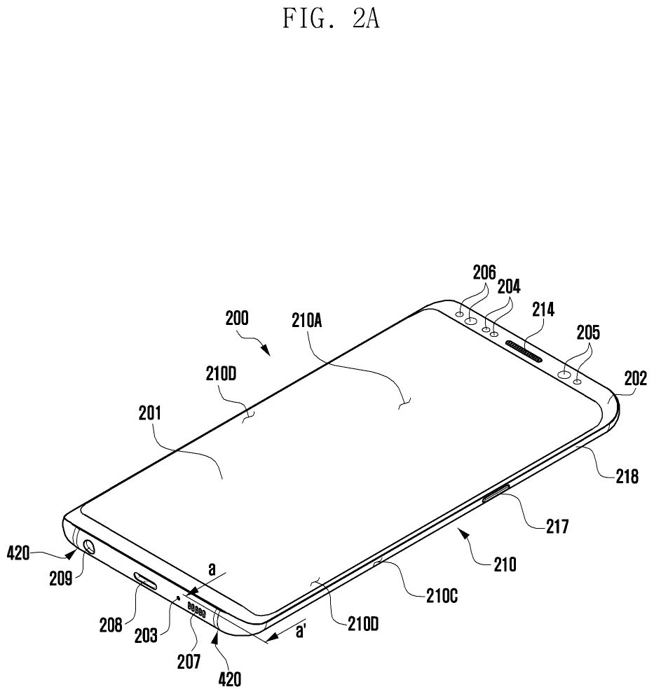

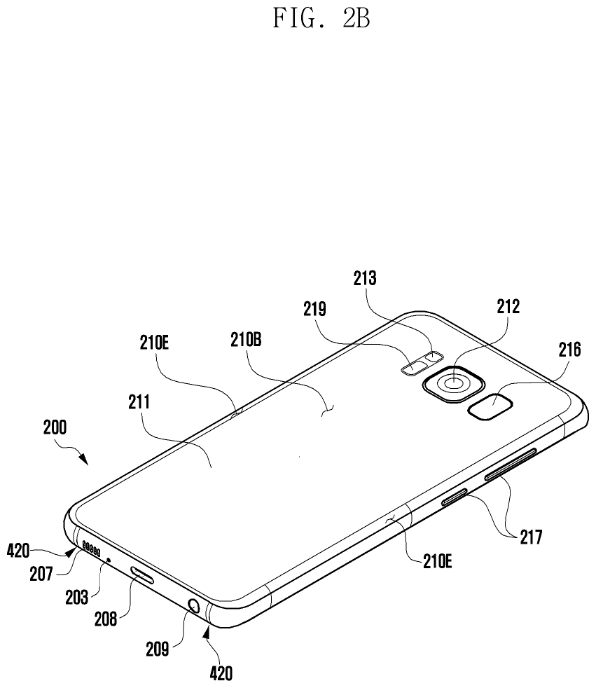

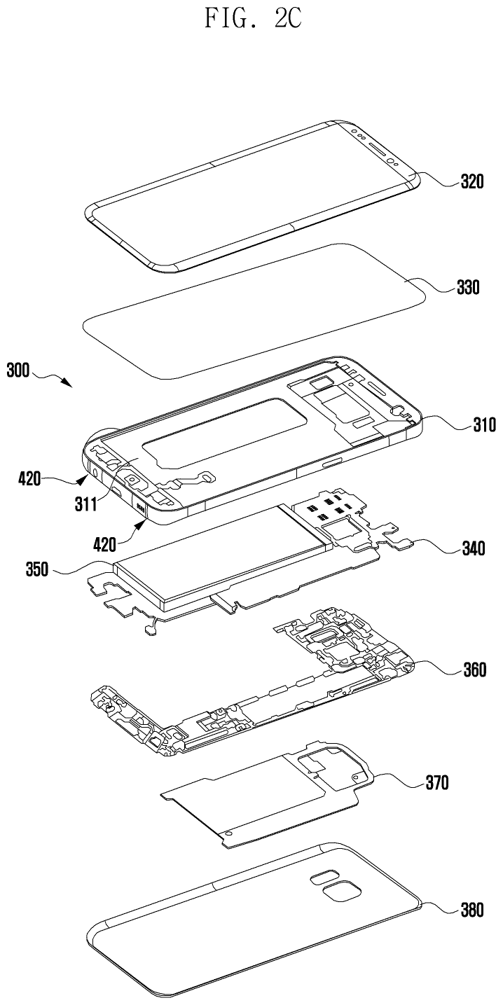

FIG. 2A is a front perspective view of an electronic device 200 according to various embodiments of the disclosure. FIG. 2B is a rear perspective view of an electronic device 200 according to various embodiments of the disclosure.

Referring to FIG. 2A and FIG. 2B, an electronic device 200 according to an embodiment may include a housing 210 including a first surface (or front surface) 210A, a second surface (or rear surface) 210B, and a lateral surface 210C surrounding the space defined between the first surface 210A and the second surface 210B. In an embodiment (not illustrated), the housing 210 may refer to a structure forming a portion of an outer surface of the electronic device 200, like some of the first surface 210A, the second surface 210B, and the lateral surface 210C in FIG. 2A. According to an embodiment, the first surface 210A may be formed by a front plate 202 (for example, a glass plate including various coating layers, or a polymer plate), at least a part of which is substantially transparent. The second surface 210B may be formed by a rear plate 211 which is substantially opaque. The rear plate 211 may be formed by (or include) coated or colored glass, ceramic, a polymer, a metal (for example, aluminum, stainless steel (STS), or magnesium), or a combination of at least two of the above materials, for example. The lateral surface 210C may be formed by a lateral bezel structure (or “lateral member”) 218 which is coupled to the front plate 202 and the rear plate 211, such as to connect the front plate 202 and the rear plate 211 to each other, and which includes a metal and/or a polymer. The lateral member 218 together with the front plate 202 and the rear plate 211 may define a receiving space in which other electrical components of the electronic device 200 are received. In embodiments, the rear plate 211 and the lateral bezel structure 218 may be formed (or provided) integrally and may include the same material (for example, a metal material such as aluminum). As being integral, elements may together define a single, unitary body.

The electronic device 200 and various components or layers thereof may be disposed in a plane defined by a first direction (e.g., extended along the long sides) and a second direction (e.g., extended along the short sides) which intersect each other. A thickness of the electronic device 200 and various components or layers thereof may be defined along a third direction intersecting both the first and second directions. The third direction may indicate a thickness direction of the electronic device 200 and various components or layers thereof. A plan view (or a plane view) may be a view along the third direction (e.g., the thickness direction), without being limited thereto.

In the illustrated embodiment, the front plate 202 may include two first regions 210D extended along long edges of the front plate 202 so as to extend seamlessly while being bent from opposing sides of the first surface 210A toward the rear plate 211. In the illustrated embodiment (refer to FIG. 2B), the rear plate 211 may include two second regions 210E extended along long edges thereof so as to extend seamlessly while being bent from opposing sides of the second surface 210B toward the front plate 202. In an embodiment, the front plate 202 (or the rear plate 211) may include only one of the first regions 210D (or the second regions 210E). In other embodiments, some of the first regions 210D or the second regions 210E may be excluded (e.g., not included).

In the above-described embodiments, when seen from a lateral surface of the electronic device 200, the lateral bezel structure 218 may have a first thickness (or width) near a lateral surface not including the above-mentioned first regions 210D or second regions 210E, and may have a second thickness smaller than the first thickness near a lateral surface including the first regions 210D or second regions 210E.

According to an embodiment, the electronic device 200 may include at least one of a display 201, audio modules 203, 207, and 214, sensor modules 204, 216, and 219, camera modules 205, 212, and 213, a key input device 217, a light-emitting element 206, and connector holes 208 and 209. In embodiments, at least one component (for example, the key input device 217 or the light-emitting element 206) of the electronic device 200 may be omitted, or other components may be additionally included.

The display 201 may be exposed to (or viewable from) outside of the electronic device 200 through a corresponding portion of the front plate 202, for example. In embodiments, at least a part of the display 201 may be exposed the to the outside through the front plate 202 forming the first regions 210D of the lateral surface 210C, together with the first surface 210A. In embodiments, the display 201 may have a corner formed in substantially the same shape as an adjacent outer periphery of the front plate 202, in a plan view. In another embodiment (not illustrated), in order to expand the area (e.g., a planar area) in which the display 201 is exposed, the interval between the outer periphery of the display 201 and the outer periphery of the front plate 202 may be formed substantially identical, such as to coincide with or be aligned with each other.

In another embodiment (not illustrated), a recess or an opening may be formed in a part of the screen display region of the display 201, and at least one of an audio module 214, a sensor module 204, a camera module 205, and a light-emitting element 206 may be aligned with the recess or opening. In another embodiment (not illustrated), at least one of an audio module 214, a sensor module 204, a camera module 205, a fingerprint sensor 216, and a light-emitting element 206 may be provided on the back surface of the screen display region of the display 201. In another embodiment (not illustrated), the display 201 may be coupled to or disposed adjacent to a touch sensing circuit, a pressure sensor capable of measuring the intensity (pressure) of a touch, and/or a digitizer configured to detect a magnetic-type stylus pen. In embodiments, at least a part of the sensor modules 204 and 219 and/or at least a part of the key input device 217 may be disposed in the first regions 210D and/or the second regions 210E.

The audio modules 203, 207, and 214 may include a microphone hole 203 and speaker holes 207 and 214. The microphone hole 203 may have a microphone disposed therein so as to acquire outer sounds (e.g., sounds or audio signals from outside of the electronic device 200), and may have multiple microphones disposed therein such that the direction of sounds can be sensed, in embodiments. The speaker holes 207 and 214 may include an outer speaker hole 207 and a communication receiver hole 214. In embodiments, the speaker holes 207 and 214 and the microphone hole 203 may be implemented as a single hole, or a speaker may be included without the speaker holes 207 and 214 (for example, a piezoelectric speaker).

The sensor modules 204, 216, and 219 may generate an electric signal or a data value corresponding to the internal operating state of the electronic device 200, or the external environment state. The sensor modules 204, 216, and 219 may include, for example, a first sensor module 204 (for example, a proximity sensor) disposed on the first surface 210A of the housing 210, and/or a second sensor module (not illustrated) (for example, a fingerprint sensor), and/or a third sensor module 219 (for example, an HRM sensor) disposed on the second surface 210B of the housing 210, and/or a fourth sensor module 216 (for example, a fingerprint sensor). The fingerprint sensor may be disposed not only on the first surface 210A (for example, the display 201) of the housing 210, but also on the second surface 210B thereof. The electronic device 200 may further include a sensor module (not illustrated), for example, at least one of a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, or an illuminance sensor 204.

The camera modules 205, 212, and 213 may include a first camera device 205 disposed on the first surface 210A of the electronic device 200, a second camera device 212 disposed on the second surface 210B thereof, and/or a flash 213. The camera devices 205 and 212 may include a single lens or multiple lenses, an image sensor, and/or an image signal processor. The flash 213 may include, for example, a light-emitting diode or a xenon lamp. In embodiments, two or more lenses (an infrared camera, a wide-angle lens, and a telephoto lens) and image sensors may be disposed on one surface of the electronic device 200.

The key input device 217 may be disposed on the lateral surface 210C of the housing 210. In another embodiment, the electronic device 200 may not include a part or all of the above-mentioned key input device 217, and the key input device 217 not included therein may be implemented on the display 201 in another type (for example, a soft key). In embodiments, the key input device may include a sensor module 216 disposed on the second surface 210B of the housing 210.

The light-emitting element 206 may be disposed on the first surface 210A of the housing 210, for example. The light-emitting element 206 may provide state information of the electronic device 200 in an optical type, for example. In another embodiment, the light-emitting element 206 may provide a light source interworking with operations of the camera module 205, for example. The light-emitting element 206 may include, for example, an LED, an IR LED, and a xenon lamp.

The connector holes 208 and 209 may include a first connector hole 208 capable of receiving a connector (for example, a USB connector) for transmitting/receiving power and/or data with an external electronic device, and/or a second connector hole (for example, an earphone jack) 209 capable of receiving a connector for transmitting/receiving audio signals with the external electronic device.

FIG. 2C is an exploded perspective view of an electronic device 300 according to various embodiments of the disclosure.

Referring to FIG. 2C, the electronic device 300 may include a lateral bezel structure 310 (for example, a housing), a first support member 311 (for example, a bracket), a front plate 320, a display 330, a printed circuit board 340, a battery 350, a second support member 360 (for example, a rear case), an antenna 370, and a rear plate 380. In embodiments, at least one component (for example, the first support member 311 or the second support member 360) of the electronic device 300 may be omitted, or other components may be included. At least one of the components of the electronic device 300 may be identical or similar to at least one of the components of the electronic device 200 in FIG. 2A or FIG. 2B, and repeated descriptions thereof will be omitted herein. For example, the display 330 may correspond to the display module 160, the display 201, etc. The display 330 may generate an image which is displayed at a screen display region of the electronic device 300 and visible from outside thereof.

The first support member 311 may be disposed in the electronic device 300 and connected to the lateral bezel structure 310 (for example, a housing), or may be formed integrally with the lateral bezel structure 310. The first support member 311 may be made of or include, for example, a metal material and/or a nonmetal material (for example, a polymer).

The display 330 may be coupled to one surface (e.g., a first surface) of the first support member 311, and the printed circuit board 340 may be coupled to the other surface thereof (e.g., a second surface opposite to the first surface). A processor, a memory, and/or an interface may be mounted on the printed circuit board 340. The processor may include, for example, at least one of a central processing device, an application processor, a graphic processing device, an image signal processor, a sensor hub processor, or a communication processor.

The memory may include, for example, a volatile memory or a nonvolatile memory.

The interface may include, for example, a high definition multimedia interface (HDMI) interface, a universal serial bus (USB) interface, an SD card interface, and/or an audio interface. The interface may, for example, connect the electronic device 300 to an external electronic device electrically or physically, and may include a USB connector, an SD card/MMC connector, or an audio connector.

The battery 350 is a device for supplying power to at least one component of the electronic device 300, and may include, for example, a primary battery which is not rechargeable, a secondary battery which is rechargeable, or a fuel cell. At least a part of the battery 350 may be disposed on substantially the same plane with the printed circuit board 340, for example. The battery 350 may be disposed integrally inside the electronic device 300, or disposed to be attachable to/detachable from the electronic device 300.

The antenna 370 may be disposed between the rear plate 380 and the battery 350. The antenna 370 may include, for example, a near field communication (NFC) antenna, a wireless charging antenna, and/or a magnetic secure transmission (MST) antenna. The antenna 370 may, for example, perform short range communication with an external device or wirelessly transmit/receive power necessary for charging. In another embodiment, an antenna structure may be formed by a part or a combination of the lateral bezel structure 310 and/or the first support member 311.

Referring to FIG. 2A to FIG. 2C, the housing 110 (or lateral bezel structure 310) of the electronic device 200 or 300 may be separated or divided by using at least one insulation region 420 and thus used as multiple antenna radiators.

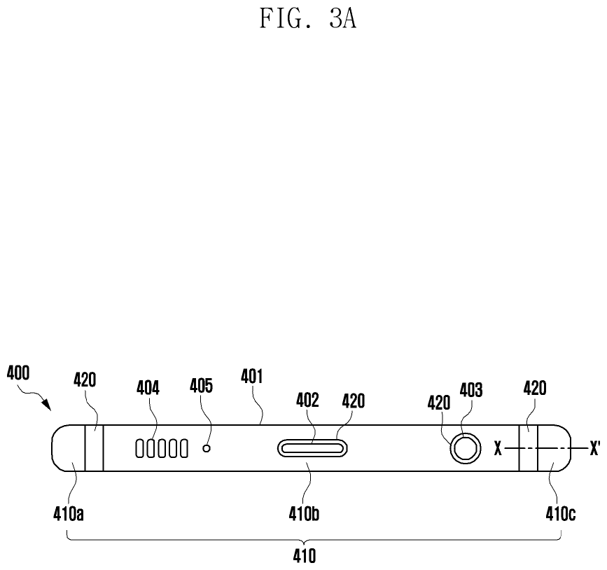

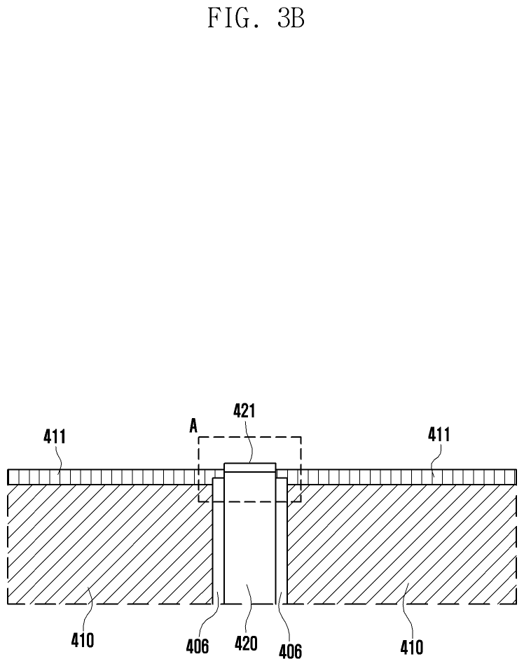

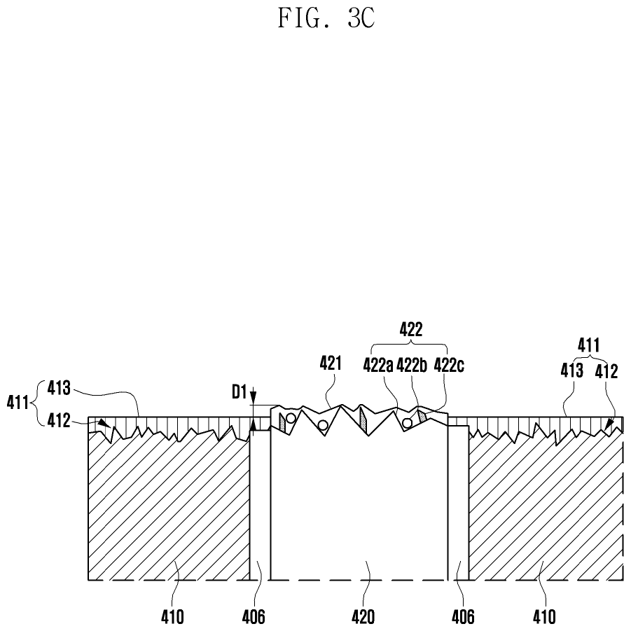

FIG. 3A is a lateral (or side) view of a housing 401 of an electronic device 400 according to various embodiments of the disclosure.

FIG. 3B is a cross-sectional view of the housing 401 of the electronic device 400.

FIG. 3C is an enlarged cross-sectional view of the housing 401 of the electronic device 400.

FIG. 3B is a cross-sectional view taken along X-X′ in FIG. 3A. FIG. 3C is an enlarged view of part A in FIG. 3B. In FIG. 3C, the surface roughness of the housing 401 of the electronic device 400 does not conform to the actual magnification, and may be exaggerated to help understanding.

Referring to FIG. 3B, the housing 401 (for example, the housing 210 in FIG. 2A or the lateral bezel structure 310 in FIG. 2C) of the electronic device 400 may include multiple metal regions 410 and an insulation region 420 provided in plural.

The multiple metal regions 410 may constitute at least a part of the outer appearance of the electronic device 400, may give mechanical rigidity to the housing 401 which protects internal components of the electronic device 400 from external impacts, and may transmit/receive electromagnetic waves for wireless communication through a surface of a respective metal region which is exposed to the outside of the electronic device 400. The multiple metal regions 410 may include a first metal region 410a, a second metal region 410b, and a third metal region 410c which are physically spaced apart from each other in a direction along the lateral surface, and which are insulated from each other by the insulation region 420 (described later). The shape of the first to third metal regions 410a, 410b, and 410c and the interval therebetween may be configured such that the multiple metal regions have an impedance (e.g., electrical impedance) sufficient to function as an antenna for transmitting/receiving radio waves in multiple radio bands. In embodiments, the first to third metal regions 410a, 410b, and 410c may operate independently as separate antennas for transmitting/receiving radio waves in different frequency bands, respectively. In another embodiment, at least two metal regions 410 among the first to third metal regions 410a, 410b, and 410c may transmit radio waves in the same frequency band. For example, if one metal region among multiple metal regions 410 fails to transmit/receive radio waves, radio waves may be transmitted/received through another metal region among the multiple metal regions 410, thereby coping with a change in radio wave transmitting/receiving environments. As such, the multiple metal regions may operate dependently on each other.

In embodiments, the metal region 410 may have or define at least one opening formed to extend into the electronic device 400. The opening may penetrate a thickness of the housing at the respective metal region 410, to define an enclosed opening or a hole of the electronic device 400. For example, a part (for example, the second metal region 410b in FIG. 3A) of the metal region 410 may have connector holes 402 and 403 (for example, the connector holes 208 and 209 in FIGS. 2A and 2B) formed therein such that a charging cable, a wired communication cable, and/or a sound cable can extend therethrough, may have a speaker hole 404 formed therein so as to emit sound signals out of the housing 401, and may have a microphone hole 405 formed therein so as to receive external sound signals into the electronic device 400. That is, the opening may penetrate a complete thickness of the housing at the respective metal region 410 to thereby be open at opposing ends of the housing, e.g., open to the outside of the electronic device 400 and open to an inner area of the electronic device 400 at which various components are disposed.

In embodiments, the metal region 410 may include aluminum, magnesium, stainless steel, or an alloy including a combination thereof. The aluminum and aluminum alloy may have a dense oxide film, and may improve the appearance and corrosion resistance of the electronic device 400 by a surface treatment method such as anodizing.

Although not illustrated, the multiple metal regions 410 may be electrically connected to the printed circuit board (for example, the printed circuit board 340 in FIG. 2C) of the electronic device 400 through respective conductive members (for example, cables). Respective metal regions 410a, 410b, and 410c may be electrically separated from each other by the insulation region 420 (described later). In embodiments, the multiple metal regions 410 electrically separated or electrically insulated from each other may independently transmit/receive electromagnetic waves according to different wireless communication methods, or may transmit/receive electromagnetic waves according to a broadband communication method based on multiple carrier frequencies (for example, multiple carrier (MC), multiple input multiple output (MIMO), and/or carrier aggregation (CA)). In another embodiment, if the antenna gain of one metal region (for example, the first metal region 410a) is reduced or blocked by contact with an external element in physical contact with the electronic device 400 (such as a user's body part like a hand (not illustrated)) for holding the electronic device 400), the electronic device 400 may be controlled to communicate through another metal region (for example, the third metal region 410c), thereby maintaining the communication quality.

The insulation region 420 may be coupled to at least two of the multiple metal regions 410 which are adjacent to each other (e.g., closest to each other along the lateral side), and disposed between the adjacent metal regions 410. The insulation region 420 may electrically insulate multiple metal regions 410 coupled to the insulation region 420. To this end, the insulation region 420 may include an insulative polymer material, for example, a polymer material such as polypropylene (PP), polypropylene sulfide (PPS), polybutylene terephthalate (PBT), polyaryl etherketone (PAEK), polyether etherketone (PEEK), a combination such as a copolymer including at least one thereof.

The electronic device 400 may include multiple insulation regions 420, and respective insulation regions 420 may have different shapes, sizes, and/or materials according to the shape of spaces between the multiple metal regions 410a, 410b, and 410c in which the insulation regions 420 are positioned, and electromagnetic characteristics required for respective metal regions 410a, 410b, and 410c. Referring to FIG. 3A, for example, the insulation regions 420 may be positioned in regions between the outer peripheral surface of the connector holes 402 and 403 and the respective metal regions in order to reduce electrical short-circuiting and/or noise caused by electric contact between cables inserted into the respective connector holes 402 and 403 and the metal regions 410.

In embodiments, the polymer material may include a crystalline polymer or a semi-crystalline polymer. The crystallinity of the crystalline polymer may be about 50% to about 80%. Increased crystallinity of the polymer material may increase the resistance to fatigue and wear and chemical resistance, thereby improving the durability of the housing 401 of the electronic device 400, and may alleviate physical and chemical damage inflicted in the process of manufacturing (or providing) the housing 401 of the electronic device 400 (described later).

The insulation region 420 may include a reinforcing fiber impregnated with a polymer material. The reinforcing fiber may increase the tensile strength of the polymer material.

The reinforcing fiber may include, for example, glass fiber, aramid fiber, basalt fiber, boron fiber, or similar fiber. The glass fiber may be inexpensive and may have a high level of tensile strength, a high level of chemical resistance, and a low level of electric conductivity. A polymer material reinforced by reinforcing fiber may be a polymer composite material. In the following description, the term “polymer material” may be used to denote not only a pure polymer material, but also a polymer composite material reinforced by reinforcing fiber.

Referring to FIG. 3B, the housing 401 of the electronic device 400 may have a coating layer 421 formed on the surface of the insulation region 420 which is exposed to the outside of the electronic device 400. The coating layer 421 may include a polymer matrix and/or a siloxane-based material. That is, the coating layer 421 may include a polymer and siloxane. The polymer matrix may include, for example, epoxy, acrylate, poly methyl methacrylate (PMMA), or a combination including at least one thereof. The above-mentioned polymer matrix may have transparent and may give a predetermined level of hardness and durability to the coating layer 421. The polymer matrix may be obtained by applying a coating solution (resin-based liquid) to the surface of the insulation region 420 and then curing the same.

The siloxane-based material may be a monomer, an oligomer, or a polymer, which includes a Si—O—Si bond. The siloxane-based material may include a methyl silicon having a methyl group as a chain, for example, an oligomer or a polymer of dimethylsiloxane having the following formula:

[(CH₃)₂OSi]ₙ

Dimethylsiloxane may help maintain a small thickness when the coating layer 421 is applied, as will be described later. In addition, the siloxane-based material may increase the hydrophobicity of the polymer matrix such that the surface of the coating layer 421 is water-repellent, thereby increasing the anti-staining performance of the housing 401 of the electronic device 400.

In embodiments, the housing 401 of the electronic device 400 may include a bonding film 406 positioned between an insulation region 420 and a metal region 410, at a region in which the insulation region 420 and the metal region 410 face each other, and coupled to each of the insulation region 420 and the metal region 410. A side surface of the insulation region 420 may face a side surface of the metal region 410, and the bonding member (e.g., the bonding film 406) may be disposed between the facing side surfaces. The bonding member may contact each of the side surfaces, such as to form an interface therebetween.

The bonding film 406 may include a material having a high degree of chemical affinity with both a polymer and a metal material, for example, an adhesive component including a triazine such as a triazine diol component or a triazine thiol compound. In another embodiment, the bonding film 406 may include a layer on the surface of or the surface of the metal material itself which is modified by a silane-based compound including a vinyl group and/or an amino group. The polymer material of the insulation region 420 and the metal material of the metal region 410 may have weak coupling therebetween due to the difference in chemical characteristics between each other. The bonding film 406 as a bonding member may couple the insulation region 420 and the metal region 410 to each other, thereby preventing separation between the insulation region 420 and the metal region 410, and increasing the durability of the housing 401 of the electronic device 400.

Referring to FIG. 3C, the metal region 410 may include a surface treatment layer 411 (e.g., a surface treated layer) formed on the outer surface of the metal region 410, which is exposed to the outer surface of the electronic device 400. Portions of the surface treatment layer 411 respectively corresponding to the metal regions 410 may be coplanar with each other, such as being in a same layer as each other. As being in a same layer, elements may be formed in a same process and/or include a same material as each other, elements may be respective portions of a same material layer, elements may be on a same layer by forming an interface with a same underlying or overlying layer, etc., without being limited thereto.

In embodiments, the surface treatment layer 411 may include a roughened surface 412 obtained by forming corrugations at the outer surface of the metal region 410 by a method such as physical roughening (for example, sandblasting) and/or chemical roughening (for example, etching), thereby increasing the roughness thereof. By roughening the outer surface of the metal region 410 to define the roughened surface 412, the outer surface of the housing 401 of the electronic device 400 has reduced gloss and has a matte texture, and this may give the electronic device 400 an aesthetic appearance.

In embodiments, the surface treatment layer 411 may include an anodized layer 413 having an anodized outer surface. The anodized layer 413 may have a lower surface conforming to the shape or profile of the roughened surface 412 of the metal region 410. The anodized layer 413 may be formed by applying a current (e.g., electrical current) to the metal region 410 while being immersed in an electrolyte, thereby anodizing the outer surface of the metal region 410. The anodized layer 413 may protect the outer surface of the metal region 410 (e.g., the roughened surface 412) from wear and corrosion, and may absorb dye so as to adjust the tone of the surface treatment layer 411, thereby improving the appearance of the electronic device 400. An conductive member of the housing may include a material body (e.g., labeled as the metal region 410) together with the surface treatment layer 411. The surface treatment layer 411 may extend from the material body to define an extended portion overlapping the bonding member (e.g., the bonding film 406), without being limited thereto.

Referring back to FIG. 3C, the insulation region 420 may include multiple protrusions 422 formed at a surface exposed to the outside of the electronic device 400. The protrusions 422 of a protrusion layer may include corrugations 422a generated on or by the outer surface of the insulation region 420 due to physical and/or chemical reasons during the above-mentioned roughening surface treatment of the metal region 410, and particles of residue 422b caused by the anodizing solution. In embodiments, if the insulation region 420 includes a reinforcing fiber, the protrusions 422 may include reinforcing fiber ends 422c exposed at the outer surface of the insulation region 420 in the course of processing the housing 401.

The protrusions 422 may define a roughness or an outer surface of a main body of the insulation region 420. The coating layer 421 formed on the outer surface of the insulation region 420 may cover at least a part of the above-mentioned protrusions 422 and may fill the spaces or gaps between the multiple protrusions 422 in a direction along the insulation region 420. As the coating layer 421 fills the spaces between the protrusions 422, the roughness of the outer surface of the coating layer 421 which is furthest from the body of the insulation region 420 may be lower than the roughness of the outer surface of the body of the insulation region 420 generated by the existence of the protrusions 422. Therefore, the coating layer 421 may reduce the whitening caused by surface diffuse reflection caused by the increased surface roughness of the insulation region 420. An insulation member of the housing may include a material body (e.g., labeled as the insulation region 420) together with the coating layer 421 and various remaining materials (e.g., the particles of residue 422b, the reinforcing fiber ends 422c, etc.).

In an embodiment, the coating layer 421 may have a refractive index higher than the refractive index of the atmosphere and lower than the refractive index or the protrusions 422 on the surface of the insulation region 420 (for example, the refractive index of glass fiber included in the reinforcing fiber, or the refractive index of metal salt included in residue 422b particles) such that the coating layer 421 reduces the whitening caused by diffuse reflection caused by the different in refractive index between the protrusions 422 and the atmosphere.

An upper surface of the conductive member and an upper surface of the insulation member may be respective portions of an outer surface of the electronic device 400. A height or level of the upper surface may be defined at an outermost point along the respective layer among the coating layer 421 and the surface treatment layer 411. In embodiments, a level difference D1 (or distance) between the upper surface of the coating layer 421 in the insulation layer 420 and the upper surface of the surface treatment layer 411 in the metal region 410 may be about 1 micrometer or less. If the level difference D1 between the metal region 410 and the insulation region 420 is excessively larger, heavy wear occurs due to physical contact with the lateral surface of the coating layer 421 from the outside of the electronic device 400, and the lifespan of the coating layer 421 may be shortened, or the coating layer 421 may be easily peeled off. Therefore, the level difference D1 may be about 1 micrometer or less. As the material of the coating solution applied to the insulation region 420 to form the coating layer 421 includes a siloxane-based material, a coating layer 421 having a level difference D1 of about 1 micrometer or less may be formed. The detailed principle by which the level difference D1 of the coating layer 421 is about 1 micrometer or less will be described later.

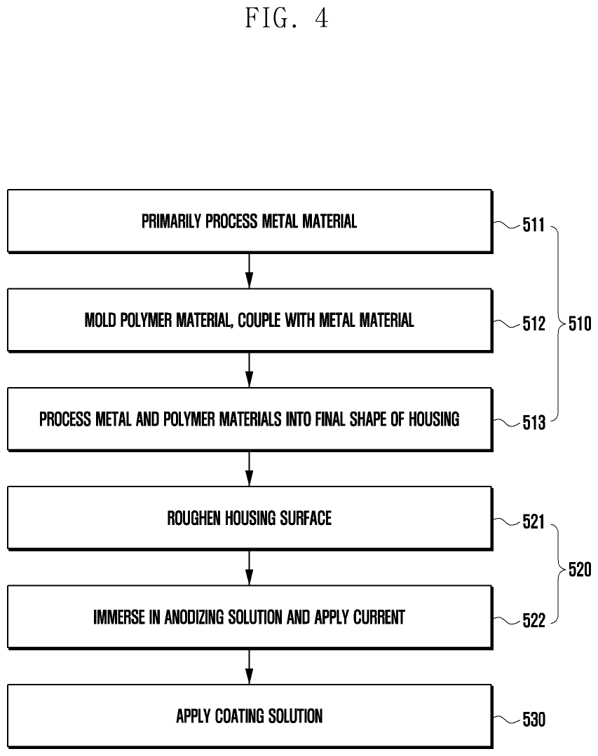

FIG. 4 is a flowchart illustrating a method for manufacturing (or providing) a housing 401 of an electronic device 400 according to various embodiments of the disclosure.

Referring to FIG. 4, the method for manufacturing a housing 401 of an electronic device 400 may include a material molding operation 510, a surface treatment operation 520, and a coating operation 530.

In the material molding operation 510, a metal material and/or a polymer material constituting the housing 401 of the electronic device 400 may be molded according to a default shape. In embodiments, the material molding operation 510 may include a first processing operation 511, a molding operation 512, and a second processing operation 513.

The first processing operation 511 may include an operation of primarily processing (roughing) a metal material to be molded into a metal region 410 of the housing 401. The metal material may be aluminum, magnesium, stainless steel, or an alloy including at least one thereof (e.g., a combination thereof). In order to process the above-mentioned metal material, a method such as casting, diecasting, milling, and/or CNC machining may be used.

In embodiments, the first processing operation 511 may include an operation of applying a bonding material layer to the facing surface of the processed metal material. The bonding material layer may attach the metal material to the polymer material in the molding operation 512 (described later).

In embodiments, in the first processing operation 511, multiple metal regions (for example, the first metal region 410a, the second metal region 410b, and the third metal region 410c in FIG. 3A) included in the housing 401 may be connected to each other by a connecting metal member (not illustrated) and thus molded into a single metal processed object (e.g., a single body). Electric separation between the multiple metal regions 410 may be accomplished by processing and removing the connecting member in the second processing operation 513 (described later).

In the molding operation 512, a polymer material included in an insulation region 420 may be molded, and coupled to the metal processed object molded in the first processing operation 511 described above. In an embodiment, the molding operation 512 may include an operation of injecting and molding a raw material of the insulation region 420 (e.g., an insulation material), including a polymer material, into the space between the multiple metal regions 410, which have been completed the first processing operation 511, in a molten or semi-molten state. In another embodiment, the molding operation 512 may include compression molding, transfer molding, or a similar method for molding a polymer and a polymer composite material.

In embodiments, the molding operation 512 may include an operation in which, prior to performing the operation of molding the raw material of the insulation region 420 and coupling the same to the metal region 410, a bonding film 406 as a bonding member is formed on the facing surface of the metal material abutting the polymer composite material by using an electrolyte or non-electrolyte coating method. The bonding film 406 may include a triazine compound, for example, a triazine diol component or a triazine thiol compound. In another embodiment, the operation of forming a bonding film 406 may include an operation of modifying the surface of the metal material with a silane compound including a vinyl group and/or an amino group. By injecting, compressing, and/or transfer molding a polymer while a bonding film 406 is formed in the metal region 410, heterogenous coupling between the polymer and metal may be made, thereby preventing the metal region 410 and the insulation region 420 from detaching from each other.

In the second processing operation 513, the metal material and polymer material fabricated and coupled to each other in the molding operation 512 may be subjected to finishing processing into the final shape of the housing 401 of the electronic device 400. In the second processing operation 513, a precise machining method, for example, CNC machining, may be used such that a precise shape of the housing 401 of the electronic device 400 can be implemented. As described above, if multiple metal regions 410 have been processed while being connected to each other by a connecting (metal) member according to an embodiment, the connecting member may be removed by machining in the second processing operation 513.

Here, a preliminary housing may be formed including an outer surface corresponding to both the metal region 410 and the insulation region 420. The outer surface of the preliminary housing may be an untreated surface.

In the surface treatment operation 520, the untreated surface of multiple metal regions 410 of the housing 401 of the electronic device 400 may be subjected to surface treatment, thereby endowing a texture and/or improving corrosion resistance.

In embodiments, the surface treatment operation 520 may include a roughening operation 521 and/or an anodizing operation 521.

In the roughening operation 521, the untreated surface of the metal material may be roughened. The roughening operation 521 may include a physical roughening operation 521 (for example, blasting) in which metals, sand, and/or ceramic particles are sprayed to the surface of the housing 401 in a preliminary form thereof, to form corrugations 422a at the outer surface of the housing 401, and/or a chemical roughening operation 521 (for example, etching) in which the housing 401 is immersed in a corrosive solution (for example, acid, base, or salt solution) to form corrugations 422a on the outer surface of the metal region 410. The corrosive solution may include various acids, such as hydrochloric acid, nitric acid, sulfuric acid, citric acid, or oxalic acid, for example, or alkaline solution such as sodium hydroxide.

In the anodizing operation 521, the housing 401 in a preliminary form thereof may be immersed in an anodizing solution, for example, phosphoric acid, sulfuric acid, chromic acid, sodium hydroxide aqueous solution, potassium dichromate aqueous solution, or a combination thereof, and a current (e.g., an electrical current) may be applied to form an anodized layer 413 at the outer surface of the metal region 410. In embodiments, the anodizing operation 521 may further include a dyeing operation in which dye is adsorbed in pores of the porous anodized layer 413 formed on the surface of the metal region 410 by anodizing, and/or a sealing operation in which the pores of the anodized layer 413 are sealed.

In the coating operation 530, a coating material solution including a siloxane-based material may be applied to the outer surface of the insulation region 420 which is exposed to outside of the electronic device 400, and the coating solution may be cured, thereby forming a coating layer 421 corresponding to the insulation region 420.

In embodiments, the coating solution may include paint having, as the main component thereof, a polymer serving as the matrix of the coating layer 421 and/or liquid resin including a precursor thereof, for example, epoxy resin, acrylate resin, poly methyl methacrylate (PMMA) resin, or a combination thereof including at least one thereof. In addition, the coating solution may include a solvent for dissolving the polymer matrix, for example, an organic solvent such as toluene, xylene, isopropyl alcohol, butanol, methyl ethyl ketone, methyl isobutyl ketone, diacetone alcohol, or propyleneglycol monomethylether acetate (PGMAC). If the coating solution includes an organic solvent for dissolving polymer, the coating solution may partially dissolve the polymer material of the surface of the insulation region 420, thereby alleviating the surface roughness. In another embodiment, the coating solution may include resins cured by a curing agent, a catalyst, ultraviolet rays, or electron beams.

The coating solution may include a siloxane-based material monomer, oligomer, or polymer, including a Si—O—Si bond. In embodiments, the siloxane-based material may include a methyl silicon having a methyl group as a chain, for example, dimethylsiloxane. If added to the coating solution, the siloxane-based material may decrease the viscosity of the coating solution, thereby increasing the fluidity of the coating solution. In addition, the coating solution including a siloxane-based material may have increased affinity with the polymer material included in the insulation region 420.

When paint is applied to the roughened outer surface of the insulation region 420 including a polymer material, a primer may be applied due to the insufficient bonding between the paint and the polymer material, and the viscosity of the paint may thicken the paint layer. Therefore, the level difference D1 between the outer surface defined by the surface treatment layer 411 and outer the surface of the paint corresponding to a conventional insulation region may exceed 1 micrometer. In one or more embodiment, if a siloxane-based material is included in the coating solution, the coating solution may have reduced viscosity, increased fluidity, and excellent bonding with the polymer material, thereby forming a coating layer 421 for which the level difference D1 from the outer surface treatment layer 411 of the metal region 410 to an outer surface of the coating layer 421 is about 1 micrometer or less.

In embodiments, the coating solution may be applied to the roughened outer surface of the insulation region 420 by a precise printing method. The precise printing method may include a method such as screen printing, inkjet, and/or direct printing (for example, digital direct printing (DDP)). The DDP may include an operation of applying a transferred material (for example, coating solution) onto a transfer surface by a method such as inkjet, and an operation of transferring the transferred material applied onto the transfer surface to the printing surface, thereby fixing the same onto the printing surface. Compared with a printing method involving spraying of coating solution, may reduce problems such as contamination of the peripheral portion of the coating layer 421 by scattering of the coating solution, or coating irregularity.

Formation of the coating layer 421 by curing the coating solution may be conducted by evaporating the solvent of the coating solution, or by curing the resin included in the coating solution by applying a curing means (for example, heat, curing agent, catalyst, ultraviolet rays, or electron beams).

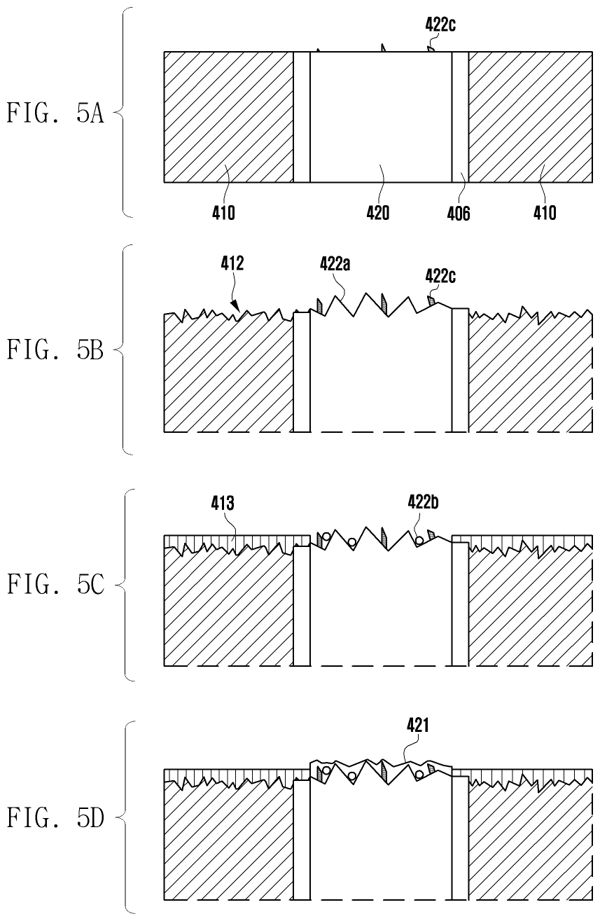

FIG. 5A, FIG. 5B, FIG. 5C, and FIG. 5D are cross-sectional views illustrating sections of a housing 401 of an electronic device 400 according to respective operations of a method for manufacturing a housing 401 of an electronic device 400 according to various embodiments of the disclosure.

Referring to FIG. 5A, after the material molding operation 510 is completed, the preliminary form of the housing 401 may have a flat/smooth outer surface as a whole. In embodiments, a remaining material such as ends 422c of reinforcing fiber included in the insulation region 420 may protrude from an outer (upper) surface of the insulation material body of the insulation region 420.

Referring to FIG. 5B, after the roughening operation 521 is completed, the preliminary form of the housing 401 may have corrugations 422a formed at the upper surface thereof, such as by a physical and/or chemical method. In embodiments, the surface roughness of the upper surface of the preliminary housing at the insulation region 420 may be larger than the surface roughness of the upper surface of the preliminary housing at the metal region 410. The larger surface roughness may result from the difference in material strength between the metal material body at the metal region 410 and the insulation material body at the insulation region 420, and may exacerbate whitening in the insulation region 420.

Referring to FIG. 5C, after the anodizing operation 522 is completed, the preliminary form of the housing 401 may have an anodized layer 413 formed as the outer surface of the metal region 410 thereof. Residues 422b of the anodizing solution may exist on the outer surface of the insulation region 420. An outer surface of the insulation material body and remaining materials thereon, may be exposed to outside the anodized layer 413, after the anodizing operation 522, without being limited thereto. The anodized layer 413 may extend from the metal material body at the metal region 410 to define an extended portion of the anodized layer 413 in a region between the metal material body and the insulation material body, in a direction along the preliminary housing.

Referring to FIG. 5D, after the coating operation 530 is completed, the housing 401 may have a coating layer 421 formed at the outer surface of the insulation region 420. As described above, the surface roughness of the upper surface defined by the coating layer 421 may be lower than the surface roughness of the upper surface defined by the insulation material body of the insulation region 420. For example, the roughness may be reduced as compared with the roughness after the roughening and/or anodizing operation 521 and 522 is completed. Therefore, whitening due to surface diffuse reflection and diffuse refraction may be prevented.

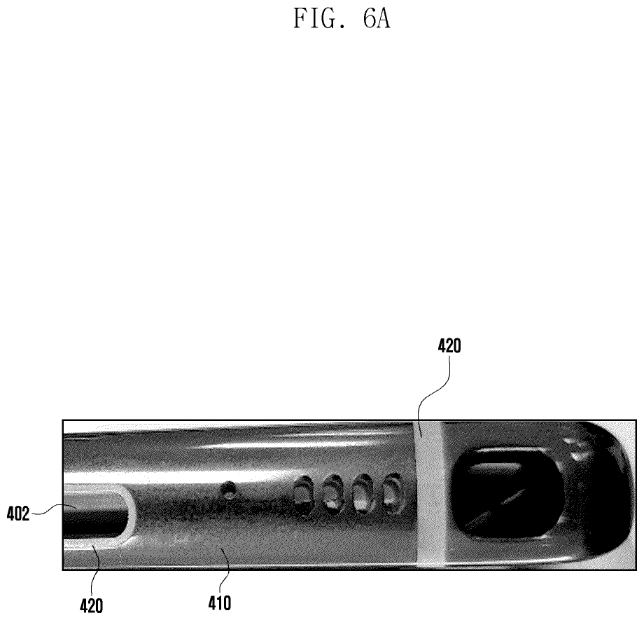

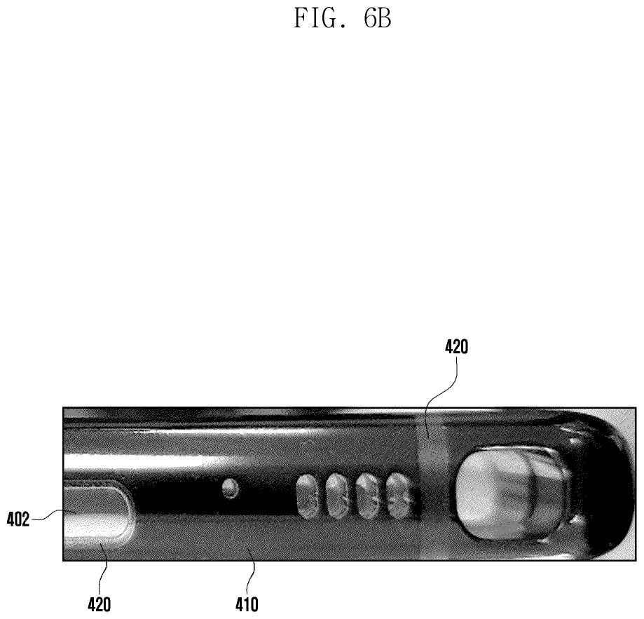

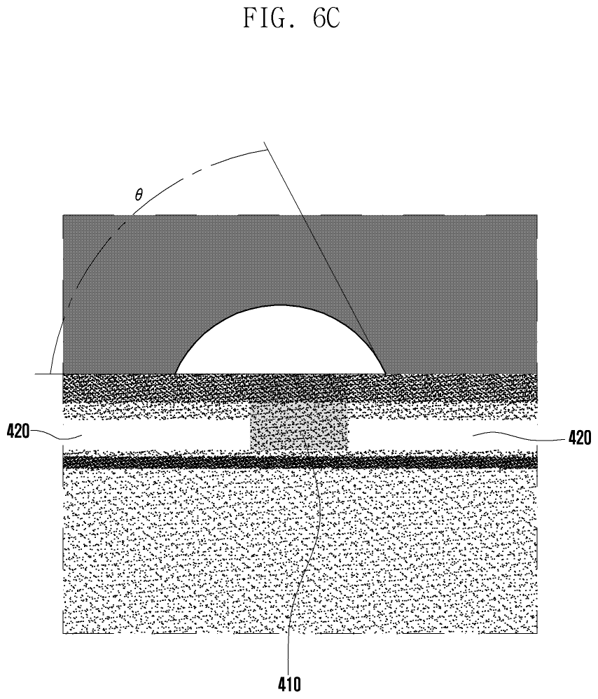

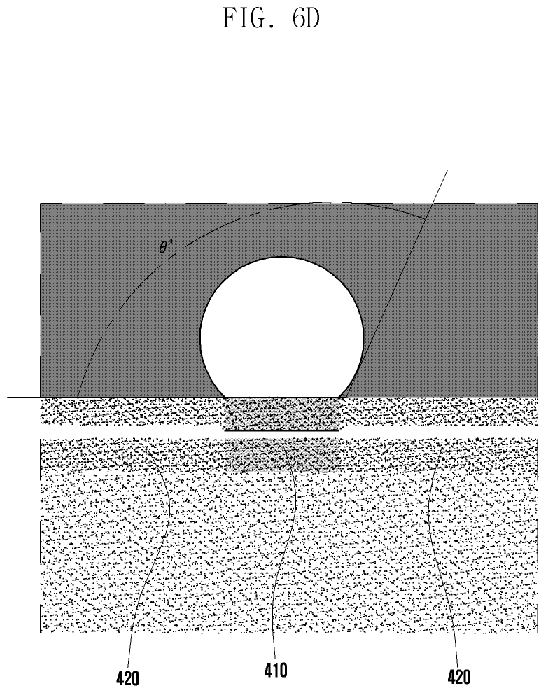

In order to identify advantageous effects of the disclosure, a housing 401 of an electronic device 400 was manufactured. In this regard, a coating solution was applied to a preliminary form of the manufactured a housing 401 according to an embodiment of the disclosure, and no coating solution was applied to a preliminary form of a comparative housing according to a comparative example. The appearance and water repellency thereof were compared. The results are illustrated in FIG. 6A to FIG. 6D.

FIG. 6A is a photograph illustrating the outer appearance of the housing 401 of the electronic device 400 according to the comparative example.

FIG. 6B is a photograph illustrating the outer appearance of the housing 401 of the electronic device 400 according to an embodiment of the disclosure.

FIG. 6C illustrates the water repellency of the housing 401 of the electronic device 400 according to the comparative example.

FIG. 6D illustrates the water repellency of the housing 401 of the electronic device 400 according to an embodiment of the disclosure.

It is obvious from FIG. 6A and FIG. 6B that the insulation region 420 of the housing 401 of the electronic device 400 according to the comparative example (FIG. 6A) has a strong whitening appearance due to surface diffuse reflection and diffuse refraction, and thus exhibits a sever surface dissimilarity relative to a directly adjacent region.

In contrast, the insulation region 420 of the housing 401 of the electronic device 400 according to an embodiment of the disclosure (FIG. 6B) has reduced surface diffuse reflection and diffuse refraction, and thus has reduced dissimilarity relative to a directly adjacent region due to the difference in surface texture and color between the insulation region 420 and the metal region 410. This advantageous effect may result from the fact that the coating layer 421 forming the outer appearance at the insulation region 420 according to the disclosure reduces surface diffuse reflection and diffuse refraction, thereby suppressing whitening. The reduced dissimilarity (an reduced whitening) may result from the siloxane-based material included in the coating layer 421 which reduces the viscosity of the coating solution, thereby lowering the outer surface roughness of the coating layer 421, and the refractive index of the coating layer 421 is lower than that of the underlying protrusions and thus reduces the reflectivity.

It is clear from FIG. 6C that the outer surface of the housing at the insulation region 420 according to the comparative example has a low level of water repellency, and the angle θ of contact with water is thus an acute angle (less than 90 degrees). In contrast, it is clear from FIG. 6D that the outer surface of the housing at the insulation region 420 according to an embodiment of the disclosure has an obtuse angle θ′ of contact with water (larger than 90 degrees). The increased water repellency is attributed to the siloxane-based material included in the coating layer 421 according to the disclosure, which increases hydrophobicity of the coating layer 421 and surface flatness/smoothness of the outer surface defined at the coating layer 421. As the outer surface of the housing 401 has water repellency, the anti-staining performance and appearance of the electronic device 400 may be improved.

In an embodiment, for example, an electronic display device includes a housing defining an outer surface of the electronic display device. The housing includes metal regions 410 including a surface treatment layer 411 defining the outer surface at the metal regions 410, an insulation region 420 which is between the metal regions 410 and coupled to each of the metal regions 410. The insulation region includes a polymer material portion (e.g., where 420 is indicated in FIGS. 3B and 3C, for example), and a coating layer 421 which is on the polymer material portion and defines the outer surface at the insulation region 420, the coating layer 421 includes a polymer matrix and siloxane. The siloxane may include dimethylsiloxane. The surface treatment layer may include an anodized layer defining the outer surface at the metal regions.

In embodiments, the outer surface which is defined by the coating layer 421 may be water-repellent.

Within the insulation region the polymer material portion may haves an upper surface (at 422a, 422b and 422c) closest to the coating layer 421, a roughness of the outer surface defined by the coating layer 421 may be lower than a roughness of the upper surface of the polymer material portion, and the outer surface defined by the metal regions 410 is a physically-roughened surface or a chemically-roughened surface.

Within the insulation region 420, the polymer matrix may include acrylate or epoxy polymer, and the coating layer may have transparency. Referring to FIG. 3C, for example, within the insulation region 420 the polymer material portion (material body where 420 is indicated) has an upper surface closest to the coating layer 421, and the upper surface includes protrusions 422 having a refractive index, and the coating layer 421 covers the protrusions 422 and has a refractive index lower than the refractive index of the protrusions 422.

The housing may further include bonding members which respectively couple the polymer material portion (material body where 420 is indicated) of the insulation region to the metal regions 410.

The electronic display device may further include a display (like 160 in FIG. 1, 201 in FIG. 2A or 330 in FIG. 2C) which provides an image. The housing may further include a front surface, a rear surface opposite to the front surface, and a side surface (like the lateral surface 210C formed by a lateral bezel structure 218 in FIGS. 2A and 2B or the lateral bezel structure 310 in FIG. 2C) which connects the front surface to the rear surface to provide a receiving space in which the display is disposed. The metal regions 410 and the insulation region 420 are arranged along the side surface of the housing (refer to FIG. 3A, for example).

A method for manufacturing an electronic device housing includes coupling a metal material (portions labeled 410 in FIG. 5A) of a metal region of the electronic device housing and a polymer material (portion labeled 420 in FIG. 5A) of an insulation region of the electronic device housing to each other, to form a coupled metal material and polymer material, machining the coupled metal material and polymer material to provide a preliminary electronic device housing having a preliminary outer surface and a contour corresponding to a final shape of the electronic device housing (within operation 510 of FIG. 4), treating the preliminary outer surface at the metal material (transition from FIG. 5A to FIG. 5B and/or FIG. 5C, for example), and applying a coating solution including a liquid resin polymer matrix and a siloxane material, to the preliminary outer surface at the polymer material (transition from FIG. 5B and/or FIG. 5C to FIG. 5D, for example)

The coupling of the metal material and the polymer material to each other may include providing a bonding member which is between the metal material and the polymer material and couples the metal material to the polymer material within the coupled metal material and polymer material (to provide the structure of FIG. 5A, for example. The machining of the coupled metal material and polymer material may include providing the preliminary outer surface at each of the metal material, the bonding member and the polymer material within the preliminary electronic device housing (FIG. 5B, for example). Here, the treating of the preliminary outer surface at the metal material may include an anodizing operation including immersing the preliminary electronic device housing in an anodizing solution and applying an electrical current to form an anodized layer on the preliminary outer surface at the metal material, where the anodized layer extends from the metal material to the bonding member (as seen in FIG. 5C, for example).

The applying of the coating solution may include printing the coating solution on the preliminary outer surface at the polymer material. The printing of the coating solution may include digital direct printing. The coating solution may include acrylate or epoxy paint, together with an organic solvent configured to dissolve the polymer material, and the siloxane may include dimethylsiloxane.

The machining of the coupled metal material and polymer material includes a first processing operation 511 including roughing the metal material of the metal region to form a processed metal region, a molding operation 512 including molding of the polymer material to form a molded polymer material and coupling the molded polymer material and the processed metal material to each other, and a second processing operation 513 of finishing the molded polymer material and the processed metal material which are coupled to each other, to form the preliminary electronic device housing having the contour corresponding to the final shape of the electronic device housing (the structure in FIG. 5A, for example).

The treating of the preliminary outer surface may include a roughening operation 521 to increase a surface roughness of the preliminary outer surface at the metal material (transition from FIG. 5A to 5B, for example). The roughening operation may include a blasting operation including spraying beads to the preliminary outer surface at the metal material or immersing the preliminary electronic device housing in a corrosive solution to etch the preliminary outer surface at the metal material.

The treating of the preliminary outer surface at the metal material may include an anodizing operation 522 including immersing the preliminary electronic device housing in an anodizing solution and applying an electrical current to form an anodized layer on the preliminary outer surface at the metal material (transition from FIG. 5B to FIG. 5C, for example).

In addition, embodiments disclosed in this document, the drawings, and this document are only specific examples presented to easily describe the technical content according to embodiments disclosed in this document and to help understanding of embodiments disclosed in this document, and are not intended to limit the scope of embodiments disclosed in this document. Therefore, the scope of various embodiments disclosed in this document is to be interpreted as encompassing all changed or modified forms derived based on the technical idea of various embodiments disclosed in this document, in addition to the embodiments disclosed herein.

What is claimed is:

1. An electronic device comprising:
a housing defining an outer surface of the electronic device,
wherein the housing comprises:
metal regions comprising a surface treatment layer defining the outer surface at the metal regions;
an insulation region which is between the metal regions and coupled to each of the metal regions, the insulation region comprising:
a polymer material portion, and
a coating layer which is on the polymer material portion and defines the outer surface at the insulation region, the coating layer comprising a polymer matrix and siloxane.

2. The electronic device of claim 1, wherein the outer surface which is defined by the coating layer is water-repellent.

3. The electronic device of claim 1, wherein
within the insulation region:
the polymer material portion has an upper surface closest to the coating layer, and
a roughness of the outer surface defined by the coating layer is lower than a roughness of the upper surface of the polymer material portion, and
the outer surface defined by the metal regions is a physically-roughened surface or a chemically-roughened surface.

4. The electronic device of claim 1, wherein the siloxane comprises dimethylsiloxane.

5. The electronic device of claim 1, wherein the surface treatment layer comprises an anodized layer defining the outer surface at the metal regions.

6. The electronic device of claim 1, wherein within the insulation region:
the polymer matrix comprises acrylate or epoxy polymer, and
the coating layer has transparency.

7. The electronic device of claim 6, wherein
within the insulation region:
the polymer material portion has an upper surface closest to the coating layer, and
the upper surface comprises protrusions having a refractive index, and
the coating layer covers the protrusions and has a refractive index lower than the refractive index of the protrusions.

8. The electronic device of claim 1, further comprising bonding members which respectively couple the polymer material portion of the insulation region to the metal regions.

9. The electronic device of claim 1, wherein the level difference between the surface of the surface treatment layer and the surface of the coating layer is 1 micrometer or less.

10. A method for manufacturing an electronic device housing, the method comprising:
coupling a metal material of a metal region of the electronic device housing and a polymer material of an insulation region of the electronic device housing to each other, to form a coupled metal material and polymer material;
machining the coupled metal material and polymer material to provide a preliminary electronic device housing having a preliminary outer surface and a contour corresponding to a final shape of the electronic device housing;
treating the preliminary outer surface at the metal material; and
applying a coating solution comprising a liquid resin polymer matrix and a siloxane material, to the preliminary outer surface at the polymer material.

11. The method of claim 10, wherein the machining of the coupled metal material and polymer material comprises:
a first processing operation including roughing the metal material of the metal region to form a processed metal region;
a molding operation including molding of the polymer material to form a molded polymer material and coupling the molded polymer material and the processed metal material to each other; and
a second processing operation of finishing the molded polymer material and the processed metal material which are coupled to each other, to form the preliminary electronic device housing having the contour corresponding to the final shape of the electronic device housing.

12. The method of claim 10, wherein the treating of the preliminary outer surface comprises a roughening operation to increase a surface roughness of the preliminary outer surface at the metal material.

13. The method of claim 12, wherein the roughening operation comprises:
a blasting operation including spraying beads to the preliminary outer surface at the metal material; or
immersing the preliminary electronic device housing in a corrosive solution to etch the preliminary outer surface at the metal material.

14. The method of claim 10, wherein the treating of the preliminary outer surface at the metal material comprises an anodizing operation including immersing the preliminary electronic device housing in an anodizing solution and applying an electrical current to form an anodized layer on the preliminary outer surface at the metal material.

15. The method of claim 10, wherein the applying of the coating solution comprises printing the coating solution on the preliminary outer surface at the polymer material.

16. The method of claim 15, wherein the printing of the coating solution comprises digital direct printing.

17. The method of claim 10, wherein
the coating solution comprises:
acrylate or epoxy paint, and
an organic solvent configured to dissolve the polymer material; and
the siloxane comprises dimethylsiloxane.

18. The method of claim 10, wherein
the coupling of the metal material and the polymer material to each other comprises providing a bonding member which is between the metal material and the polymer material and couples the metal material to the polymer material within the coupled metal material and polymer material; and
the machining of the coupled metal material and polymer material comprises providing the preliminary outer surface at each of the metal material, the bonding member and the polymer material within the preliminary electronic device housing.
